(19) United States
(12) Patent Application Publication
(10) Pub. No.: US 2025/0066643 A1
(43) Pub. Date: Feb. 27, 2025

(54) ANISOTROPIC CONDUCTIVE ADHESIVE AND COMPOSITION THEREOF

(71) Applicant: NOPION CO., LTD., Suwon-si, Gyeonggi-do (KR)

(72) Inventors: Chang Hoon SIM, Seoul (KR); Kyung Sub LEE, Yongin-si, Gyeonggi-do (KR)

(21) Appl. No.: 18/725,458

(22) PCT Filed: Dec. 28, 2022
(86) PCT No.: PCT/KR2022/021556

§ 371 Date: Jun. 28, 2024

(30) Foreign Application Priority Data
Dec. 28, 2021 (KR) 10-2021-0190262

(51) Int. Cl. C09J 9/02; C09J 4/00; C09J 11/04; H05K 1/18; H05K 3/32

(52) U.S. Cl. CPC C09J 9/02; C09J 4/00; C09J 11/04; H05K 1/189; H05K 3/321

(57) ABSTRACT

An embodiment provides: an adhesive resin composition comprising substituted or unsubstituted dicyclopentadiene and a substituted or unsubstituted acrylic compound and having a storage modulus of 100 Pa to 1000 Pa at 100° C. to 300° C.; and self-assembling anisotropic conductive adhesive comprising the adhesive resin composition, leading to an effect of having excellent adhesion even in a flexible display or a semiconductor device.

### TECHNICAL FIELD

The present invention relates to an anisotropic conductive adhesive and, more particularly, to an anisotropic conductive adhesive used in a flexible circuit board.

### BACKGROUND ART

Entering the 21st century, semiconductor packages are becoming more highly integrated, more high-performance, less costly, and more miniaturized as information and communication devices advance. In addition, flexible displays, which have recently been attracting attention as next-generation displays, have excellent bendability and may be folded or rolled, so that research on stable electrical/mechanical characteristics and high integration of mounted microcomponents is rapidly progressing.

Accordingly, the development of high-density electronic packaging technology is actively underway, and among these electronic packaging technologies, the bonding method using anisotropic conductive adhesives (ACAs) has great advantages such as low-temperature processes and simplified processes.

In general, a chip attachment process in the production of semiconductor packages is mostly face-up, wherein a chip is attached to a printed circuit board (CB). Therefore, when attaching a chip to a flexible display or flexible circuit board, an adhesive film or adhesive that attaches the chip needs to have not only hard properties but also flexible properties.

However, in the case of resins that generally have flexible properties, there was a problem that they did not have hard properties because the storage modulus was high, and adhesion was poor because the storage modulus was low. Therefore, the development of a flexible adhesive that has flexible properties and high adhesion that is not inferior to adhesion is required.

Meanwhile, dicyclopentadiene (DCPD) is a material that is usually used as a raw material for polyester resins, and is used in various industrial fields such as adhesives and inks due to its good compatibility with other base resins, so that it is possible to explore usage ways to solve technical problems.
<Related art document> Republic of Korea Patent Publication No. 10-2020-0068204

### DETAILED DESCRIPTION OF THE INVENTION

### Technical Problem

An aspect of the present invention is to provide an anisotropic conductive adhesive that has flexible properties while also having high storage modulus and thus hard properties, and may be used in the mounting process of a flexible substrate or display.

The aspect of the present invention is not limited to that mentioned above, and other aspects not mentioned will be clearly understood by those skilled in the art from the description below.

### Technical Solution

An embodiment of the present invention provides an adhesive resin composition including substituted or unsubstituted dicyclopentadiene and a substituted or unsubstituted acrylic compound and having a storage modulus E″ of 100 Pa or more and 1000 Pa or less at 100° C. or more and 300° C. or less.

In an embodiment of the present invention, the acrylic compound may include at least one selected from the group consisting of methyl methacrylate, methyl acrylate, ethyl acrylate, butylacrylate, styrene, acrylamide, hydroxyalkyl acrylate, glycidyl methacrylate, isononyl acrylate, 2-ethylhexyl acrylic acid, methyl methacrylate, methyl acrylic acid, and acrylonitrile.

In addition, in an embodiment of the present invention, the dicyclopentadiene and the acrylic compound may have a weight ratio of 1:0.5 or more and 1:50 or less.

Another aspect of the present invention provides a self-assembling anisotropic conductive adhesive, including the adhesive resin composition of the previous embodiment; and conductive solder particles.

In an embodiment of the present invention, the solder particles may include at least one selected from the group consisting of tin (Sn), indium (In), silver (Ag), bismuth (Bi), and copper (Cu).

In addition, in an embodiment of the present invention, the solder particles may have a melting point of 70° C. or more and 250° C. or less.

In addition, in an embodiment of the present invention, in the solder particles, an oxide film may be removed.

In addition, in an embodiment of the present invention, the solder particles may be contained in a ratio of 10 to 70 volume % with respect to the total amount of the anisotropic conductive adhesive.

At this time, the solder particles may be contained in a ratio of 50 to 60 volume % with respect to the total amount of the anisotropic conductive adhesive.

In addition, in an embodiment of the present invention, the anisotropic conductive adhesive is in the form of a film or paste.

### Advantageous Effects

According to an embodiment of the present invention, an anisotropic conductive adhesive having flexible properties while having high storage modulus and thus hard properties may be provided, which may be used in a mounting process of a flexible substrate or display.

The effects of the present invention are not limited to the effects described above, and should be understood to include all effects that are inferable from the configuration of the present invention described in the detailed description or claims of the present invention.

### BRIEF DESCRIPTION OF THE DRAWINGS

FIGS. 1 to 3 are views showing the operating principle of a conventional self-assembling anisotropic conductive adhesive.

FIG. 4 is a view showing the shape of a substrate when bonding the substrate using a self-assembling anisotropic conductive adhesive of the present invention.

### MODE FOR CARRYING OUT THE INVENTION

Hereinafter, the present invention will be described with reference to the accompanying drawings. However, the present invention may be implemented in various different forms and, therefore, is not limited to the examples described herein. In order to clearly explain the present invention in the drawings, portions unrelated to the description are omitted, and similar portions are given similar reference numerals throughout the specification.

Throughout the specification, when a portion is said to be “connected (linked, contacted, combined)” with another portion, this includes not only a case of being “directly connected” but also a case of being “indirectly connected” with another member in between. In addition, when a portion is said to “include” a certain component, this does not mean that other components are excluded, but that other components may be added, unless specifically stated to the contrary.

The terms used herein are merely used to describe specific embodiments and are not intended to limit the present invention. Singular expressions include plural expressions unless the context clearly dictates otherwise. In this specification, it should be understood terms such as “include” or “have” are to designate the presence of features, numbers, steps, operations, components, parts, or combinations thereof described in the specification, but are not to exclude in advance the possibility of the presence or addition of one or more other features, numbers, steps, operations, components, parts, or combinations thereof.

Flexible displays, which have recently been attracting attention as next-generation displays, have excellent bendability, so that adhesives applied to the displays must maintain adhesion even on a flexible substrate. However, adhesives previously proposed do not maintain adhesion on the flexible substrate.

Hereinafter, an Embodiment of the Present Invention Will be Described in Detail with Reference to the Accompanying Drawings

In an embodiment of the present invention, in order to solve the technical problem, a self-assembling anisotropic conductive adhesive (hereinafter, referred to as “SACA”) is provided, including an adhesive resin composition of an embodiment described below; and conductive solder particles.

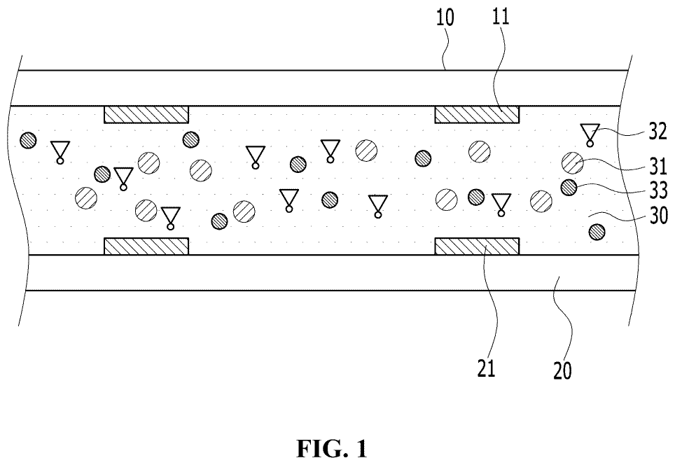

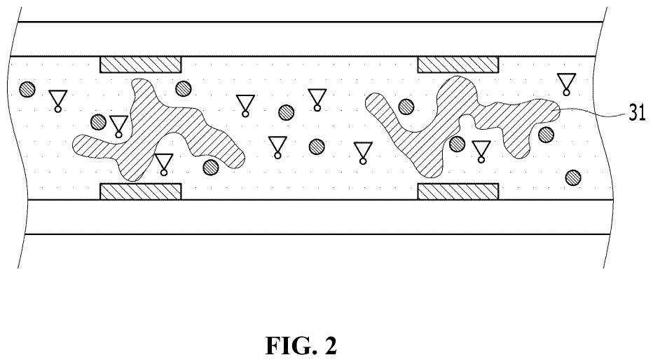

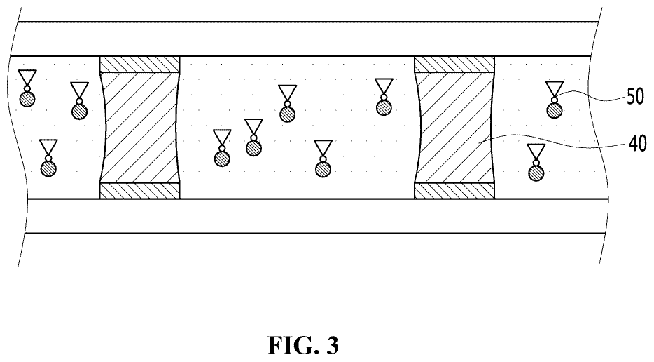

FIGS. 1 to 3 are views showing the operating principle of a conventional self-assembling anisotropic conductive adhesive.

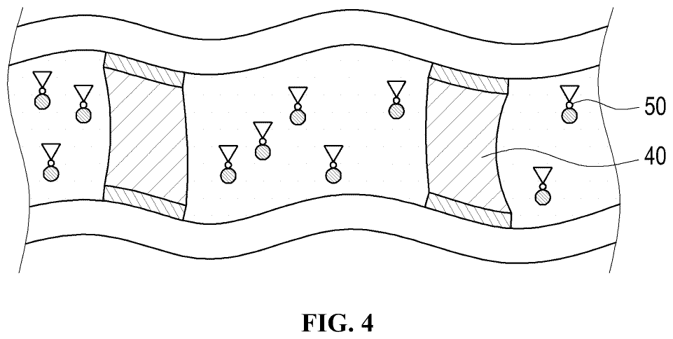

FIG. 4 is a view showing the shape of a substrate when bonding the substrate using a self-assembling anisotropic conductive adhesive of the present invention.

As seen from FIGS. 1 to 3, when using a conventional self-assembling anisotropic conductive adhesive, a substrate or display therefor had an inflexible structure. Therefore, even after the self-assembling anisotropic conductive adhesive was hardened, no external force while the substrate became flexible was applied to the hardened conductive adhesive.

On the other hand, when the substrate performs a flexible function, as seen from FIG. 4, when the substrate is bonded using the self-assembling anisotropic conductive adhesive of the present invention, the substrate may have various curved surfaces because this corresponds to a flexible display or substrate, wherein the hardened adhesive may also have various curves accordingly, and the hardened adhesive should not have its adhesive strength weakened and should be maintained.

As described above, the self-assembling anisotropic conductive adhesive provides an anisotropic conductive adhesive including an adhesive resin composition in which a dicyclopentadiene compound and an acrylic compound are mixed to control the storage modulus, thereby enabling use in a component mounting process or a contact process step of a flexible display or a flexible circuit board.

At this time, depending on the degree of flexibility of a flexible display or flexible circuit board and the process temperature and use temperature of the flexible display or flexible circuit board, the degree of flexibility of the self-assembling anisotropic conductive adhesive of the present invention used by a user may also vary.

Considering the specific usage conditions and usage methods, it is preferable that the flexibility of the self-assembling anisotropic conductive adhesive of the present invention has a storage modulus (E″) of 100 Pa or more and 1000 Pa or less at 100° C. or more and 300° C. or less.

### Hereinafter, Before Describing the SACA Provided by the Embodiment, an Adhesive Resin Composition Provided by Another Embodiment of the Present Invention Will be First Described.

An embodiment of the present invention provides an adhesive resin composition including substituted or unsubstituted dicyclopentadiene and a substituted or unsubstituted acrylic compound and having a storage modulus (E″) of 100 Pa or more and 1000 Pa or less at 100° C. or more and 300° C. or less.

At this time, regarding the inclusion of the substituted or unsubstituted dicyclopentadiene and the substituted or unsubstituted acrylic compound, the compounds undergo a polymerization reaction to form a polymer mixture. The polymer mixture produced through the polymerization reaction likewise may be used as an adhesive resin composition having flexibility.

At this time, the adhesive resin composition has flexibility and may be used in various flexible displays or flexible circuit boards, and the flexibility of the flexible displays or flexible circuit boards also varies.

Accordingly, in order to be used in the above-described various flexible displays or flexible circuit boards, it is preferable that the adhesive resin composition has a storage modulus (E″) of 100 Pa or more and 1000 Pa or less at 100° C. or more and 300° C. or less, as described above.

### Hereinafter, the Components of the Adhesive Resin Composition Will be Described.

The substituted or unsubstituted dicyclopentadiene in the adhesive resin composition has a very high cohesive force between polymer chains, and is added to the adhesive resin composition so as to impart high toughness and adhesion to the bonding material when bonding flexible circuit boards, and at this time, it is preferable that the adhesive resin composition containing the dicyclopentadiene has a tensile strength of 1.0 kgf/cm or more.

By adding the dicyclopentadiene, the adhesive resin composition may form a strong bond when hardened, thereby providing an effect of increasing the initial tensile strength.

However, when the adhesive resin composition is exposed to repeated external impacts such as high temperature, low temperature, and moisture, the adhesion may be destroyed at the interface between the flexible circuit board and the adhesive resin composition due to the very high cohesion between polymer chains due to the characteristics of the dicyclopentadiene material. Therefore, it is necessary to supplement through polymerization with a substance that may compensate for the disadvantage of the adhesion being destroyed at the interface without compromising the advantage of high cohesion.

The substituted or unsubstituted acrylic compound in the adhesive resin composition has a ductile property due to low chain fluidity, and provides flexibility to the bonding material when bonding between flexible circuit boards; therefore, addition to the adhesive resin composition is made so that when the adhesive resin composition is exposed to repeated external impacts such as high temperature, low temperature, and moisture, the adhesion is not destroyed at the interface between the flexible circuit board, which is relatively weak to external impacts, and the adhesive resin composition, but a cohesive failure occurs inside the adhesive resin composition that is relatively resistant to external impact, and by adding the acrylic compound, an effect of increasing long-term reliability may be obtained

Therefore, the acrylic compound may be one selected from the group including, for example, methyl methacrylate, methyl acrylate, ethyl acrylate, butylacrylate, styrene, acrylamide, hydroxyalkyl acrylate, glycidyl methacrylate, isononyl acrylate, 2-ethylhexyl acrylic acid, methyl methacrylate, methyl acrylic acid, and acrylonitrile, but is not limited to the examples above.

### Hereinafter, the Solder Particles Will be Described.

### The Composition of the Solder Particles Will be Described First.

The solder particles are conductive particles, and are located between the adherends after a component mounting process, and are particles that act as wires that transmit electricity. Accordingly, the solder particles may be conductive metal particles, may include at least one selected from the group consisting of tin (Sn), indium (In), silver (Ag), bismuth (Bi), and copper (Cu), and preferably have a melting point of 70° C. or more and 250° C. or less. However, it should be interpreted that the compositions that may be easily changed and adopted by a person having ordinary knowledge in the same technical field, such as conjugated polymers and conductive polymers, to achieve the effects of the present invention are all included in this right.

In addition, when the solder particles are metal elements, they easily form an oxide film on the surface by contacting oxygen in the atmosphere. When mounting electronic components such as semiconductor chips using anisotropic conductive adhesives containing solder particles due to the generated oxide film, there is a problem that unstable electrical characteristics such as low conductivity and unstable bonding strength occur due to unstable contact resistance. As a method for solving this, in a step of mixing and dispersing the solder particles and binder resin, solder particles with improved wetting through a reducing agent such as carboxylic acid may be used to strengthen the bonding with wiring and signal line contacts.

That is, when the solder particles are metal elements, they may form an oxide film, and therefore, it is preferable that in the solder particles, an oxide film is removed or controlled through a reducing agent.

### Hereinafter, the Particle Size of the Solder Particles Will be Described.

The size of the solder particles may be selected according to the size of the applied conductive pattern (e.g. pitch), and as the size of the conductive pattern increases, solder particles with a larger particle size may be used.

### Hereinafter, the Mixing Ratio of the Solder Particles Will be Described.

The solder particles may be contained in a ratio of 10 to 70 volume % based on the total amount of the anisotropic conductive adhesive, considering the fluidity and wetting characteristics. If the ratio is less than 10 volume %, there is a risk that the solder particles will be insufficient and that the terminals will not be connected, and if the ratio exceeds 70 volume %, there is a risk that the solder particles will remain excessively and cause a bridge between adjacent terminals by a connector, resulting in a short circuit.

### Hereinafter, the Physical Properties and Characteristics of the Self-Assembling Anisotropic Conductive Adhesive Will be Described.

The anisotropic conductive adhesive, as described above, includes the conductive solder particles and the adhesive resin composition. The anisotropic conductive adhesive may have a viscosity of 10,000 cps or more and 500.000 cps or less in a temperature range of 100° C. or more and 250° C. or less.

In addition, the anisotropic conductive adhesive may be used in a film form or a paste form. However, it is preferable to use a film-type conductive adhesive for substrate mounting. This is because the film form is superior to the paste form in terms of quality management such as electronic component mounting cost, thickness management, and adhesive reliability.

In addition, in the case of the film form, the adhesive may be produced by considering the width of the adherends, and if produced to be the same width as the adherends, adhesion may be performed without separate additional processing, which may create an advantage in the process.

In addition, as seen through the experiment described below, the anisotropic conductive adhesive has adhesion of 2.0 to 3.0 kgf/cm and, at the same time, excellent contact resistance, and thus, compared to the anisotropic conductive adhesives previously proposed, has high potential for use as a mounting conductive adhesive in various industrial fields such as substrates, displays, and semiconductors.

Hereinafter, the present invention will be described in more detail through Production Examples and Experimental Examples. However, the present invention is not limited to Production Examples and Experimental Examples below.

### Production Example 1

In this Production Example 1, a dicyclopentadiene compound and an acrylic compound were mixed with a hydroxyalkyl acrylate compound to produce an anisotropic conductive adhesive.

The specific process steps are as follows.

10 g of dicyclopentadiene epoxy and 15 g of hydroxyalkyl acrylate epoxy were mixed at 30° C. for 30 minutes to form a mixture.

1 g of a silane coupling agent was mixed with the mixture at 25° C. for 10 minutes.

25 g of solder particles containing In and Sn and 1 g of a reducing agent were additionally mixed with the mixture at 25° C. for 10 minutes, and finally 5 g of a hardening agent was additionally mixed at 25° C. for 1 minute.

Through the above process, in this Production Example 1, it was possible to produce an adhesive resin composition successfully.

### Experimental Example 1

In this Experimental Example 1, the storage modulus of various anisotropic conductive adhesives produced in Production Example 1 was measured.

The specific experimental method was to measure the storage modulus in the temperature range of 100° C. to 300° C. using a rheometer.

As a result of the experiment, it was possible to see that the storage modulus was in the range of 500 Pa to 5,000 Pa in the temperature range of 100° C. to 300° C., and as seen in Experimental Example 2 described below, the storage modulus in the range of 100 Pa to 1,000 Pa in the temperature range of 100° C. to 300° C. showed the best adhesion in a flexible display.

### Experimental Example 2

In this Experimental Example 2, component mounting was performed in a flexible display using the anisotropic conductive adhesive of Production Example 1.

The specific experimental method is as follows.

First, an anisotropic conductive adhesive film was bonded to a flexible lower substrate at a temperature of 60° C. under a pressure of 1 Mpa, and then the flexible lower substrate to which the film was bonded and the opposing upper substrate were aligned.

Thereafter, bonding was performed at 180° C. for 10 seconds under a pressure of 1 kg in the lower substrate-film-upper substrate state, and then an adhesion test was performed.
1. Used tool: UTM (Universal Testing Machine)
2. Used base material: PCB and FPCB adhesion (200 pitch)
3. Experiment conditions: tensile speed 50 mm/min, 90° peel

As a result of the experiment, it is possible to see that the anisotropic conductive adhesives including adhesive resin compositions having a storage modulus of 100 Pa to 1,000 Pa in a temperature range of 100° C. to 300° C. exhibit the best effects.

### Experimental Example 3

In this Experimental Example 3, an experiment was conducted to confirm the type of flexible adherent applicable, when using the anisotropic conductive adhesive synthesized in Production Example 2.

The specific experimental method was the same as the experimental method of Experimental Example 2, except that the type of flexible adherent was different.

The adherents used in the experiment in this Experimental Example 3 were four types, which are PI, PET, PCT, and Ultra thin glass.

As a result of the experiment, it was possible to see that excellent effects were exhibited in various types of flexible adhesives.

### Production Example 2

In this Production Example 2, in Production Example 1, only the ratio of solder particles was changed to 10/15/ . . . volume %, and various anisotropic conductive adhesives were produced in the same manner.

As a result, anisotropic conductive adhesives containing solder particles having various component ratios were successfully produced. The effect of changing the ratio of the solder particles was confirmed in Experimental Example 4 described below.

### Experimental Example 4

In this Experimental Example 4, the adhesion was confirmed using an anisotropic conductive adhesive containing various ratios of solder particles produced in Production Example 2.

As a result, as shown in Table 1, it was possible to see that the adhesion was the best when the solder particle ratio was about 50 to 60 volume %.

TABLE 1

| | Solder particle | |
|---|---|---|
| Entry | volume % | Adhesion |
| — | — | — |
| 1 | 10 | X |
| 2 | 15 | X |
| 3 | 20 | X |
| 4 | 25 | X |
| 5 | 30 | X |
| 6 | 35 | X |
| 7 | 40 | ◯ |
| 8 | 45 | ◯ |
| 9 | 50 | ⊚ |
| 10 | 55 | ⊚ |
| 11 | 60 | ⊚ |
| 12 | 65 | ◯ |
| 13 | 70 | ◯ |

The description of the present invention described above is for illustrative purposes, and those skilled in the art will understand that the present invention is easily modifiable into other specific forms without changing the technical idea or essential features of the present invention. Therefore, the examples described above should be understood in all respects as illustrative and not restrictive. For example, each component described as single may be implemented in a distributed manner, and similarly, components described as distributed may also be implemented in a combined form.

The scope of the present invention is indicated by the claims described below, and all changes or modified forms derived from the meaning and scope of the claims and their equivalent concepts should be construed as being included in the scope of the present invention.

### EXPLANATION OF REFERENCE NUMERALS

10: Second substrate
11: Connection terminal
20: First substrate
21: Electrode terminal
30: Self-assembling anisotropic conductive adhesive
31: Solder particles
32: Binder resin (or adhesive resin composition)
33: Hardening agent
40: Connector
50: Hardened resin layer

1. An adhesive resin composition comprising:
substituted or unsubstituted dicyclopentadiene; and
a substituted or unsubstituted acrylic compound,
wherein the adhesive resin composition has a storage modulus of 100 Pa or more and 1000 Pa or less at 100° C. or more and 300° C. or less.

2. The adhesive resin composition of claim 1, wherein the dicyclopentadiene and the acrylic compound have a weight ratio of 1:0.5 or more and 1:50 or less.

3. The adhesive resin composition of claim 1, wherein the acrylic compound comprises at least one selected from a group consisting of methyl methacrylate, methyl acrylate, ethyl acrylate, butylacrylate, styrene, acrylamide, hydroxyalkyl acrylate, glycidyl methacrylate, isononyl acrylate, 2-ethylhexyl acrylic acid, methyl methacrylate, methyl acrylic acid, and acrylonitrile.

4. A self-assembling anisotropic conductive adhesive, comprising:
the adhesive resin composition of claim 1; and
conductive solder particles.

5. The self-assembling anisotropic conductive adhesive of claim 4, wherein the solder particles comprise at least one selected from a group consisting of tin (Sn), indium (In), silver (Ag), bismuth (Bi), and copper (Cu).

6. The self-assembling anisotropic conductive adhesive of claim 4, wherein the solder particles have a melting point of 70° C. or more and 250° C. or less.

7. The self-assembling anisotropic conductive adhesive of claim 4, wherein in the solder particles, an oxide film is removed.

8. The self-assembling anisotropic conductive adhesive of claim 4, wherein the solder particles are contained in a ratio of 10 to 70 volume % with respect to a total amount of the anisotropic conductive adhesive.

9. The self-assembling anisotropic conductive adhesive of claim 8, wherein the solder particles are contained in a ratio of 50 to 60 volume % with respect to a total amount of the anisotropic conductive adhesive.

10. The self-assembling anisotropic conductive adhesive of claim 4, wherein the anisotropic conductive adhesive is in a form of a film or paste.
